(19) United States
(12) Patent Application Publication
(10) Pub. No.: US 2008/0157146 A1
(43) Pub. Date: Jul. 3, 2008

(54) IMAGE SENSOR AND METHOD FOR FABRICATING THE SAME

(76) Inventors: Jung-Kyu Kim, Seoul (KR); Yeo-Jo Yun, Seoul (KR)

Correspondence Address: SHERR & NOURSE, PLLC, 620 HERNDON PARKWAY, SUITE 200, HERNDON, VA, 20170, US

(21) Appl. No.: 11/959,235

(22) Filed: Dec. 18, 2007

(30) Foreign Application Priority Data
Dec. 28, 2006 (KR) 10-2006-0135859

(51) Int. Cl. H01L 33/00; H01L 21/00

(52) U.S. Cl. 257/292; 438/70; 257/E21.001; 257/E31.001

(57) ABSTRACT

An image sensor includes: a photodiode and a transistor formed in a semiconductor substrate that is defined as a device isolation region and an active region; a first interlayer insulating film formed over the semiconductor substrate; a metal wire formed over the first interlayer insulating film; a second interlayer insulating film formed over the first interlayer insulating film including the metal wire; and a color filter layer and a micro lens formed over the second interlayer insulating film. The first interlayer insulating film includes a first tetraethyl orthosilicate (TEOS) film, a first hydrogen silsequioxane (HSQ) film, and a second tetraethyl orthosilicate film, which are sequentially laminated.

The present application claims priority under 35 U.S.C. 119 to Korean Patent Application No. 10-2006-0135859 (filed on Dec. 28, 2006), which is hereby incorporated by reference in its entirety.

### BACKGROUND

An image sensor may be fabricated by depositing an interlayer insulating film on and/or over a semiconductor substrate including a photodiode and a transistor and forming a color filter layer and a micro lens through a wiring process. In order to form the color filter layer, the interlayer insulating film may be planarized. Planar material has been mainly used to prevent occurrence of diffuse reflection from silicon (Si) and other materials during the planarization process.

Where an image may be displayed using an image sensor fabricated by the above process, there may be a drawback of the generation of hair defects. Regarding a cause of the hair defect, when a display is realized, there may occur a hair-shaped defect because a uniform stress is not applied to a whole surface of a wafer after the color filter layer has been formed.

### SUMMARY

Embodiments relate to an image sensor and a method for fabricating the same that can prevent the occurrence of hair defects.

Embodiments relate to an image sensor that can include: a photodiode and a transistor formed in a semiconductor substrate defined by a device isolation region and an active region; a first interlayer insulating film formed over the semiconductor substrate; a metal wire formed over the first interlayer insulating film; a second interlayer insulating film formed over the first interlayer insulating film including the metal wire; and a color filter layer and a micro lens formed over the second interlayer insulating film. In accordance with embodiments, the first interlayer insulating film includes a multilayer structure.

Embodiments relate to a method for fabricating an image sensor that can include at least one of the following steps: forming a photodiode and a transistor in a semiconductor substrate defining a device isolation region and an active region; forming a first interlayer insulating film over the semiconductor substrate; forming a metal wire over the first interlayer insulating film; forming a second interlayer insulating film over the first interlayer insulating film including the metal wire; and then forming a color filter layer and a micro lens over the second interlayer insulating film. In accordance with embodiments, the first interlayer insulating film has a multilayer structure.

Embodiments relate to a method for fabricating an image sensor that can include at least one of the following steps: providing a semiconductor substrate having a photodiode and a transistor formed therein, the semiconductor substrate defining a device isolation region and an active region; forming a first multilayer interlayer insulating film including a first tetraethyl orthosilicate film, a first hydrogen silsequioxane film, and a second tetraethyl orthosilicate film over the semiconductor substrate; forming a metal wire over the first interlayer insulating film; forming a second multilayer interlayer insulating film including a third tetraethyl orthosilicate film, a second hydrogen silsequioxane film, and a fourth tetraethyl orthosilicate film over the first multilayer interlayer insulating film including the metal wire; and then forming a color filter layer and a micro lens over the second multilayer interlayer insulating film.

### DRAWINGS

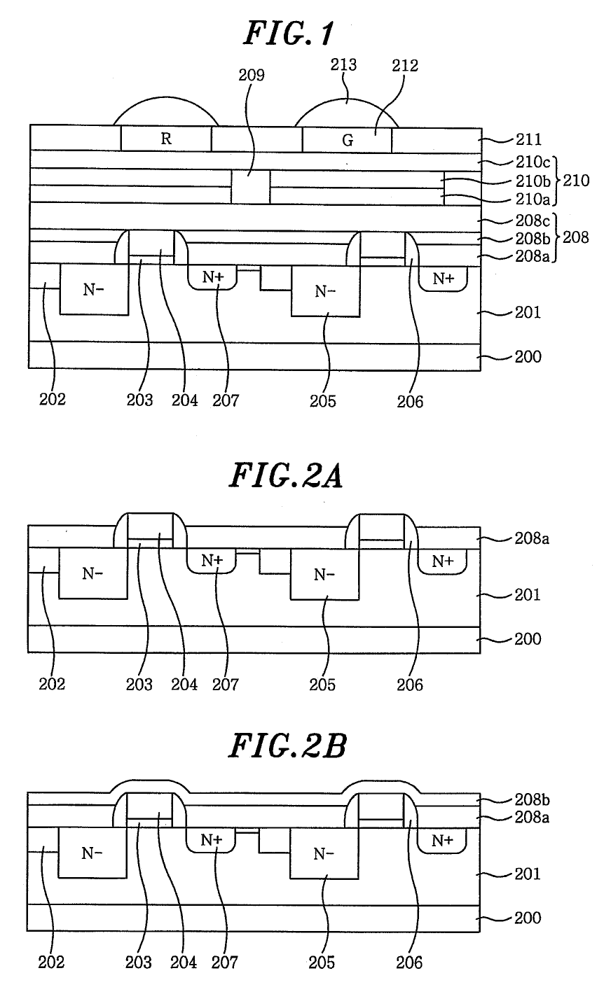

Example FIG. 1 illustrates an image sensor, in accordance with embodiments.

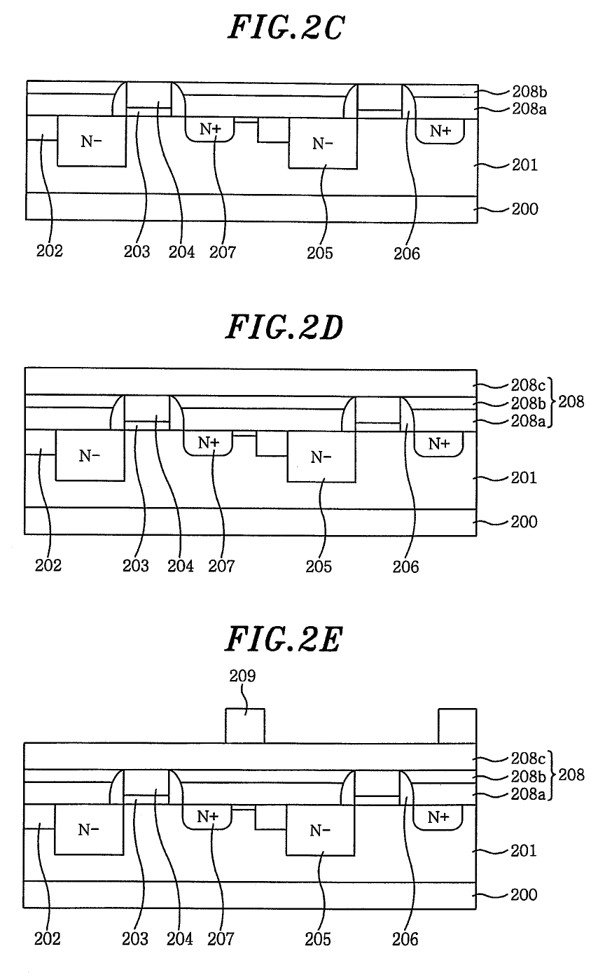

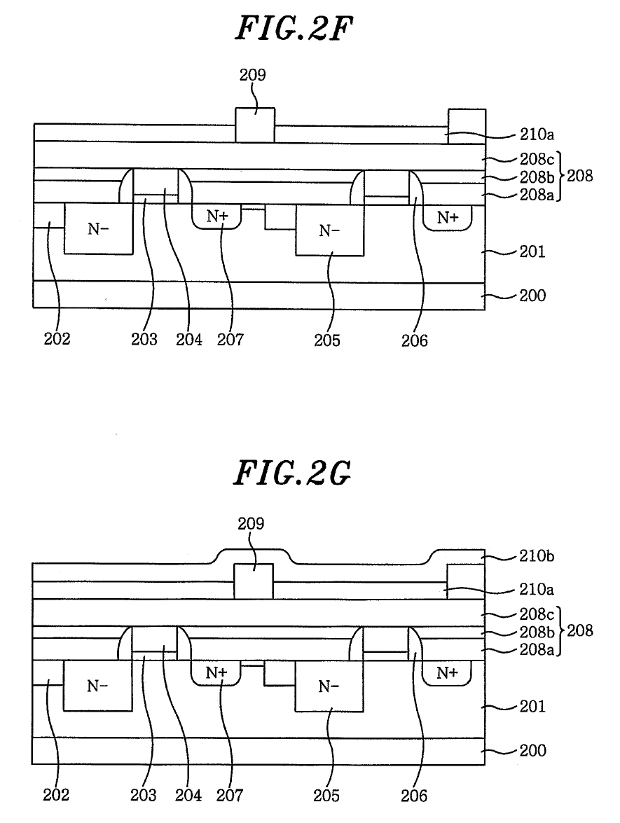

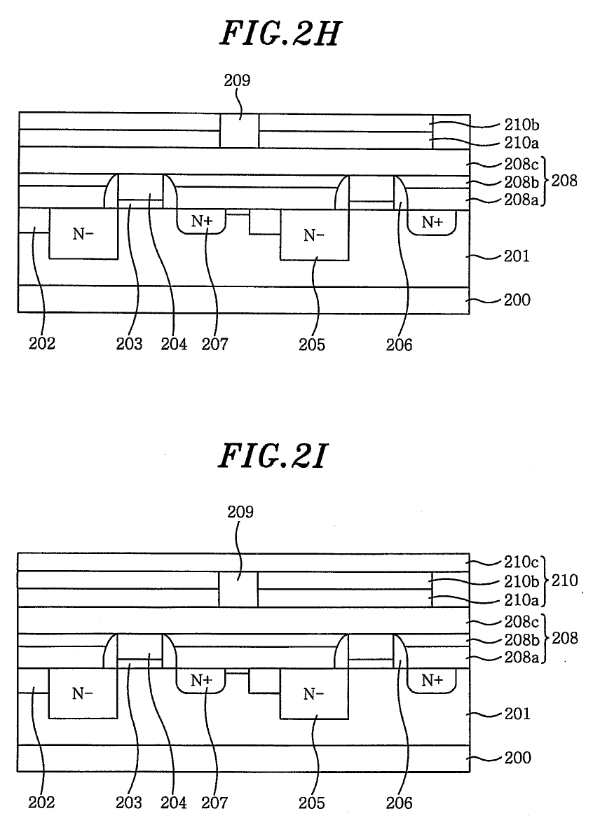

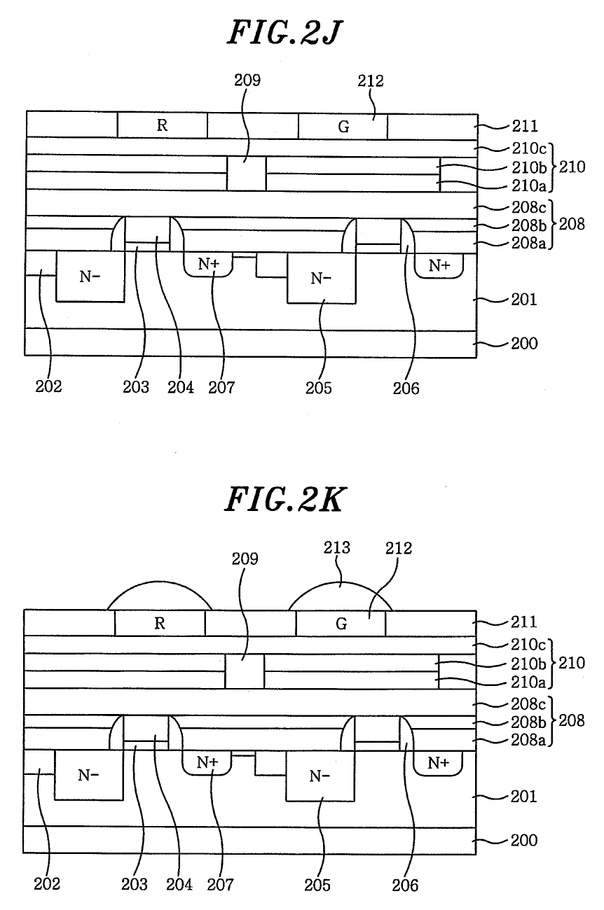

Example FIGS. 2A to 2K illustrate a method for fabricating an image sensor, in accordance with embodiments.

### DESCRIPTION

As illustrated in example FIG. 1, an image sensor in accordance with embodiments can include P⁻-type epitaxial layer 201 formed on and/or over P⁺⁺-type semiconductor substrate 200 defined as a device isolation region and an active region (a photodiode region and a transistor region). Field oxide film 202 for isolation between input regions for green light, red light, and blue light can then be formed in the device isolation region of semiconductor substrate 200. Gate insulating film 203 can then be formed on and/or over epitaxial layer 201 and gate electrode 204 formed on and/or over gate insulating film 203 in the active region of semiconductor substrate 200.

N⁻-type diffusion region 205 can then be formed in the photodiode region of semiconductor substrate 200. Sourced/drain 207 region can be formed in semiconductor substrate 200. Insulating film sidewalls 206 can then be formed at both side surfaces of gate insulating film 203 and gate electrode 204.

First interlayer insulating film 208 can then be formed on and/or over a whole surface of semiconductor substrate 200 including gate electrode 204. First interlayer insulating film 208 can include a multilayer structure including tetraethyl orthosilicate (TEOS) film 208a, hydrogen silsequioxane (HSQ) film 208b, and TEOS film 208c. A plurality of metal wires 209 can then be formed at regular intervals on and/or over first interlayer insulating film 208.

Second interlayer insulating film 210 can then be formed on and/or over a whole surface of semiconductor substrate 200 including first interlayer insulating film 208 and metal wires 209. Second interlayer insulating film 210 can include a multilayer structure including TEOS film 210a, HSQ film 210b, and TEOS film 210c. Nitride film 211 can then be formed on and/or over second interlayer insulating film 210.

Nitride film 211 can be selectively removed correspondingly to N⁻-type diffusion region 205. Thus, trenches can be formed at a predetermined depth from a surface. Red (R), Green (G), and Blue (B) color filter layers 212 can then be formed in the trenches. A plurality of micro lenses 213 can then be formed on and/or over color filter layers 212 correspondingly to N⁻-type diffusion region 205.

In accordance with embodiments, first interlayer insulating film 208 and second interlayer insulating film 210 can be formed by sequentially laminating a TEOS film, an HSQ film, and a TEOS film in order to prevent generation of hair defects.

As illustrated in example FIG. 2A, a method for fabricating the image sensor in accordance with embodiments can include forming epitaxial layer 201 on and/or over semiconductor substrate 200 using an epitaxial process.

Semiconductor substrate 200 can be composed of high concentration first conductive type (P⁺⁺-type) polycrystalline silicon. Semiconductor substrate 200 can include a photodiode region, a transistor region, and a device isolation region.

Epitaxial layer 201 can be composed of a low concentration first conductive type (P⁻-type) material. Epitaxial layer 201 can be beneficial for enhancing the ability of a low voltage photodiode having a big and deep depletion region and collecting optical charges and to improve photosensitivity.

Device isolation film 202 can then be formed in the device isolation region using a Shallow Trench Isolation (STI) process or a LOCal Oxidation of Silicon (LOCOS) process.

Gate electrode 204 of each transistor can then be formed by sequentially depositing gate insulating film 203 and a conductive layer (e.g., a high concentration polycrystalline silicon layer) on and/or over a whole surface of epitaxial layer 201 including device isolation film 202. Gate insulating film 203 can be formed in a thermal oxidation process or a Chemical Vapor Deposition (CVD) method. Gate electrode 204 can then be formed by forming a silicide layer on and/or over the conductive layer. A thermal oxidation film can then be formed by thermally oxidizing gate electrode 204 and semiconductor substrate 200.

N⁻-type diffusion region 205 can then be formed by implanting low concentration second conductive type (N-type) impurity ions into the photodiode region of semiconductor substrate 200. Insulating film sidewalls 206 can then be formed at both sides of gate insulating layer 203 and gate electrode 204 by forming and etching-back an insulating film over a whole surface of semiconductor substrate 200.

High concentration N⁺-type diffusion region 207 can then be formed by implanting high concentration second conductive type (N⁺-type) impurity ions into the transistor region of semiconductor substrate 200. Impurities within N⁻-type diffusion region 205 and N⁺-type diffusion region 207 can be diffused by processing semiconductor substrate 200 by a heat treatment (e.g., a rapid heat treatment).

Before formation of high concentration N⁺-type diffusion region 207, an N⁻-type diffusion region can be formed in the transistor region using ion implantation energy lower than that of N⁻-type diffusion region 205.

As illustrated in example FIGS. 2B to 2D, first interlayer insulating film 208 can then be formed over a whole surface of semiconductor substrate 200. First interlayer insulating film 208 can have a multilayer structure including TEOS film 208a, HSQ film 208b and TEOS film 208c.

TEOS film 208a can be formed by depositing TEOS film 208a at a thickness in a range from 6000 Å to 8000 Å. Preferably, the thickness of TEOS film 208a is 7000 Å. HSQ film 208b can then be coated on and/or over TEOS film 208a using a spin-on-glass (SOG) process. HSQ film 208b can be coated and processed in a baking process. After a high portion of HSQ film 208b having a step is etched, TEOS film 208c can then be formed having a thickness in a range from 3000 Å to 5000 Å. Preferably, the thickness of TEOS film 208c is 4000 Å.

As illustrated in example FIG. 2E, a pair of metal wires 209a can be formed by depositing a metal film on and/or over first interlayer insulating film 208 and selectively etching the deposited metal film in a photolithographic process.

As illustrated in example FIG. 2F to 2I, second interlayer insulating film 210 can then be formed over a whole surface of semiconductor substrate 200 including metal wires 209. Second interlayer insulating film 210 can have a multilayer structure including TEOS film 210a, HSQ film 210b and TEOS film 210c.

Second interlayer insulating film 210 can be formed by depositing TEOS film 210a on and/or over first interlayer insulating film 208 and coating HSQ film 210b on and/or over TEOS film 210a and metal wires 209a using an SOG process. HSQ film 210b can be coated and then processed in a baking process. After a high portion of HSQ film 210b having a step is etched, TEOS film 210c can then be formed on and/or over HSQ film 210b.

In accordance with embodiments, a pair of interlayer insulating films can be formed using an SOG process so that a uniform stress can be applied to a whole surface of a semiconductor substrate, thereby improving hair defects.

As illustrated in example FIG. 2J, a plurality of trenches can then be formed having a predetermined depth by forming nitride film 211 on and/or over second interlayer insulating film 210 and selectively removing portions of nitride film 211 correspondingly to the photodiode region in a photolithographic process.

Color filter layers 212 composed of Red (R), Blue (B), and Green (G) color filter layers 212 can then be formed corresponding to respective N⁻-type diffusion regions 205 within the trenches. Color filter layers 212 can each be coated using a tingible resist on and/or over a whole surface of the resultant structure including the trenches and then are formed to filter light on a per-wavelength-range basis in an exposure and development process.

Each color filter layer 212 can have different thicknesses. Therefore, a planarization process such as Chemical Mechanical Polishing (CMP) can also be performed on and/or over a whole surface of color filter layer 212 with an uppermost surface of nitride film 211 as an end point.

As illustrated in example FIG. 2K, a photoresist for a microlens can then be coated on and/or over a whole surface of semiconductor substrate 200 including color filter layer 212 to efficiently focus light on N⁻-type diffusion region 205. A microlens pattern can then be formed by selectively patterning the photoresist in an exposure and development process.

In case where the photoresist is a positive resist, a transmittance may not be improved until a photoactive compound of an initiator, which is an absorber of the photoresist, can be decomposed. Therefore, a photoactive compound remaining within the micro lens pattern is decomposed with a flood exposure. As above, the microlens pattern can be processed with a flood exposure to improve a transmittance, and a photo acid is generated to enhance a flow ability of a microlens.

Semiconductor substrate 200 including the microlens pattern can then be placed on and/or over a hot plate and heat treated at a temperature of about 150° C. to 300° C. Thus, the microlens pattern reflows, thereby forming hemispherically-shaped microlens 213. Microlens 213 reflowing by a heat treatment can then be cooling-treated. Semiconductor substrate 200 can be cooling-treated by being placed on and/or over a cool plate.

Accordingly, an image sensor and a method for fabricating the image sensor in accordance with embodiments can prevent occurrence of hair defects in the image sensor.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a photodiode and a transistor formed in a semiconductor substrate defined by a device isolation region and an active region;
a first interlayer insulating film formed over the semiconductor substrate;
a metal wire formed over the first interlayer insulating film;
a second interlayer insulating film formed over the first interlayer insulating film including the metal wire; and
a color filter layer and a micro lens formed over the second interlayer insulating film,
wherein the first interlayer insulating film includes a multilayer structure.

2. The apparatus of claim 1, wherein the multilayer structure comprises a first tetraethyl orthosilicate film, a first hydrogen silsequioxane film, and a second tetraethyl orthosilicate film.

3. The apparatus of claim 2, wherein the first tetraethyl orthosilicate film has a thickness in a range from 6000 Å to 8000 Å.

4. The apparatus of claim 3, wherein the second tetraethyl orthosilicate film has a thickness in a range from 3000 Å to 5000 Å.

5. The apparatus of claim 2, wherein the second interlayer insulating film includes a multilayer structure.

6. The apparatus of claim 5, wherein the multilayer structure comprises a third tetraethyl orthosilicate film, a second hydrogen silsequioxane film, and a fourth tetraethyl orthosilicate film.

7. The apparatus of claim 1, further comprising a nitride film formed over the second interlayer insulating film, wherein the color filter layer is interposed in the nitride film.

8. A method comprising:
forming a photodiode and a transistor in a semiconductor substrate defining a device isolation region and an active region;
forming a first interlayer insulating film over the semiconductor substrate;
forming a metal wire over the first interlayer insulating film;
forming a second interlayer insulating film over the first interlayer insulating film including the metal wire; and then
forming a color filter layer and a micro lens over the second interlayer insulating film,
wherein the first interlayer insulating film has a multilayer structure.

9. The method of claim 8, wherein the multilayer structure is formed by sequentially laminating a first tetraethyl orthosilicate film, a first hydrogen silsequioxane film, and a second tetraethyl orthosilicate film.

10. The method of claim 9, wherein the first hydrogen silsequioxane film is coated on the first tetraethyl orthosilicate film through a spin on glass process.

11. The method of claim 10, wherein after coating the first hydrogen silsequioxane film, the first hydrogen silsequioxane film is subjected to a baking process and selective etching process to remove stepped portions thereof.

12. The method of claim 11, wherein the second interlayer insulating film includes a multilayer structure.

13. The method of claim 12, wherein the multilayer structure is formed by sequentially laminating a third tetraethyl orthosilicate film, a second hydrogen silsequioxane film, and a fourth tetraethyl orthosilicate film.

14. The method of claim 13, wherein the second hydrogen silsequioxane film is coated on the third tetraethyl orthosilicate film through a spin on glass process.

15. The method of claim 14, wherein after coating the second hydrogen silsequioxane film, the second hydrogen silsequioxane film is subjected to a baking process and a selective etching process to remove stepped portions thereof.

16. The method of claim 15, further comprising, after forming the second interlayer insulating film:
forming a nitride film over the second interlayer insulating film; and
forming trenches in the nitride film to expose the uppermost surface of the second interlayer insulating film by selectively removing portions of the nitride film corresponding to the photodiode region,
wherein the color filter layer is formed in the trenches.

17. The method of claim 16, wherein the first tetraethyl orthosilicate film has a thickness of 6000 Å to 8000 Å and the second tetraethyl orthosilicate film has a thickness of 3000 Å to 5000 Å.

18. A method comprising:
providing a semiconductor substrate having a photodiode and a transistor formed therein, the semiconductor substrate defining a device isolation region and an active region;
forming a first multilayer interlayer insulating film including a first tetraethyl orthosilicate film, a first hydrogen silsequioxane film, and a second tetraethyl orthosilicate film over the semiconductor substrate;
forming a metal wire over the first interlayer insulating film;
forming a second multilayer interlayer insulating film including a third tetraethyl orthosilicate film, a second hydrogen silsequioxane film, and a fourth tetraethyl orthosilicate film over the first multilayer interlayer insulating film including the metal wire; and then
forming a color filter layer and a micro lens over the second multilayer interlayer insulating film.
